(19) United States
(12) Patent Application Publication
(10) Pub. No.: US 2009/0289269 A1
(43) Pub. Date: Nov. 26, 2009

(54) PACKAGING STRUCTURE OF LIGHT EMITTING DIODE

(76) Inventors: Soshchin NAUM, Changhua City (TW); Wei-Hung Lo, Taipei City (TW); Chi Ruei Tsai, Taipei City (TW)

Correspondence Address: Guice Patents PLLC, 12647 Galveston Court #302, Manassas, VA, 20112, US

(21) Appl. No.: 12/400,205

(22) Filed: Mar. 9, 2009

(30) Foreign Application Priority Data
May 26, 2008 (TW) 097119325

(51) Int. Cl. H01L 33/00

(52) U.S. Cl. 257/98; 257/E33.006

(57) ABSTRACT

The present invention discloses a light-emitting diode packaging structure, comprising a base; a chip; a first material disposed on at least one side of the chip and having a first refraction index; a second material disposed upon the chip, having a second refraction index, and separated with the first material with an interface therebetween to refract the light refracted from the first material; and a ball lens disposed upon the second material and forming a confined space with the base; whereby, the light emitted from the chip refracts through the first refraction material and the second refraction material and finally emits out from the ball lens.

### FIELD OF THE INVENTION

The present invention relates to a light-emitting diode packaging structure, and in particular to a light-emitting diode packaging structure which can enhance the luminescent efficiency of light-emitting diodes.

### BACKGROUND OF THE INVENTION

The modern light-emitting diode (LED) industry has been striving to enhance LED's luminescent efficiency, which is determined by the following factors: (1) the luminescent efficiency of LED chip, including the internal efficiency which involves transforming internal electric energy into light energy in the LED chip, and the external efficiency which involves the light emitted from the chip interior to its exterior; (2) the light conversion efficiency of phosphor (if necessary); for example, the most common commercial white LED packaging structure employing blue light chip and yellow phosphor; and (3) the design of packaging structure, most of which stresses the choice of transparent materials, such as high light transmittance, high penetrability, high refractivity, high heat dissipating materials, the structural design (high-power LED), and so on.

From the perspective of optics, the LED industry has the following options to increase the luminescent efficiency: (1) using transparent or translucent substrate for LED chip, for example blue-green light chip of sapphire or SiC substrate, red-yellow GaP substrate, and so on; (2) enhancing the light emitting efficiency of the emission area of LED, increasing the roughness of the emission zone, for example; and (3) employing packaging materials with high light transmittance, high penetrability, and high refractivity.

FIG. 1 illustrates the light refraction path of a conventional surface-mount (SM) LED and FIG. 2 illustrates the light refraction path of a conventional direct in-line (DIP) LED. With reference to the figures, light emitted from the LED (or the phosphor layer) comprises front radiation 21 from its front surface and side radiation 22 and 23 from its sides. However, the side radiations 22 and 23 have to be inflected/refracted inside the packaging interior of the LED before emitting outside. The light path is long and the intensity of the light will be diminished as a result of absorption by the LED packaging materials. Furthermore, the final emitted light (light 31 and 32 denoted in FIG. 2) is no longer the target light originally designed before LED packaging.

For the optics of the LED packaging, the design of LED luminescent angle is important, apart from choosing packaging materials with high light transmittance, high penetrability, and high refractivity. The inadequate design of the luminescent angle of the LEDs shown in FIGS. 1 and 2 leads to poor luminescent efficiency, which is a drawback remained to be improved.

The present invention discloses a LED packaging structure to overcome the drawback of the design of the conventional LED packaging structure.

### SUMMARY OF THE INVENTION

One objective of the present invention is to provide a light-emitting diode (LED) packaging structure which employs two materials with different refraction indexes to refract the light emitted from a chip and then emit out through a ball lens to enhance the luminescent efficiency of LEDs.

To achieve the aforementioned objective, the present invention provides a light-emitting diode packaging structure, comprising a base disposed with a positive connection pad and a negative connection pad; a chip disposed on the base and coupled with the positive and negative connection pads with two conducting wires, respectively; a first material disposed on at least one side of the chip and having a first refraction index to refract the light emitted from the chip; a second material disposed upon the chip, having a second refraction index, and separated with the first material with an interface therebetween to refract the light refracted from the first material; and a ball lens disposed upon the second material and forming a confined space with the base; consequently, the light emitted from the chip refracts through the first refraction material and the second refraction material and finally emits out from the ball lens.

To achieve the aforementioned objective, the present invention provides a light-emitting diode packaging structure, comprising a base disposed with a first leg; a second leg disposed on one side of the base; a chip disposed on the base and coupled with the first leg and the second leg with two conducting wires, respectively; a first material disposed on at least one side of the chip and having a first refraction index to refract the light emitted from the chip; a second material disposed upon the chip, having a second refraction index, and separated with the first material with an interface therebetween to refract the light refracted from the first material; and a ball lens disposed upon the second material and forming a confined space with the base, the first leg, and the second leg; whereby, the light emitted from the chip refracts through the first refraction material and the second refraction material and finally emits out from the ball lens.

### BRIEF DESCRIPTION OF THE DRAWINGS

The present invention can be more fully understood by reference to the following description and accompanying drawings, in which:

FIG. 1 illustrates the light refraction path of a conventional surface-mount (SM) light-emitted diode (LED);

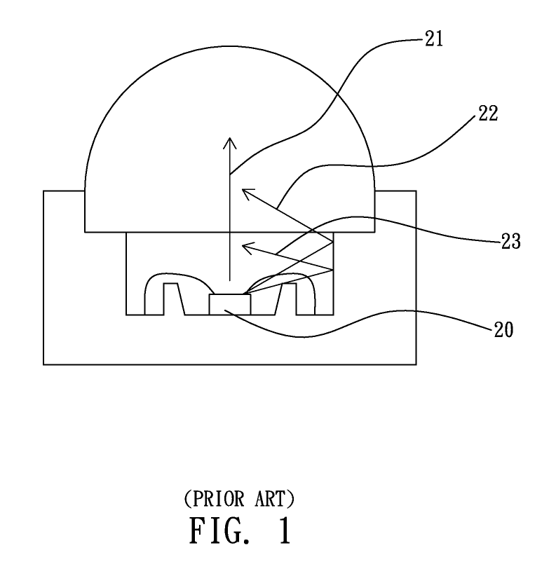

FIG. 2 illustrates the light refraction path of a conventional direct in-line (DIP) LED;

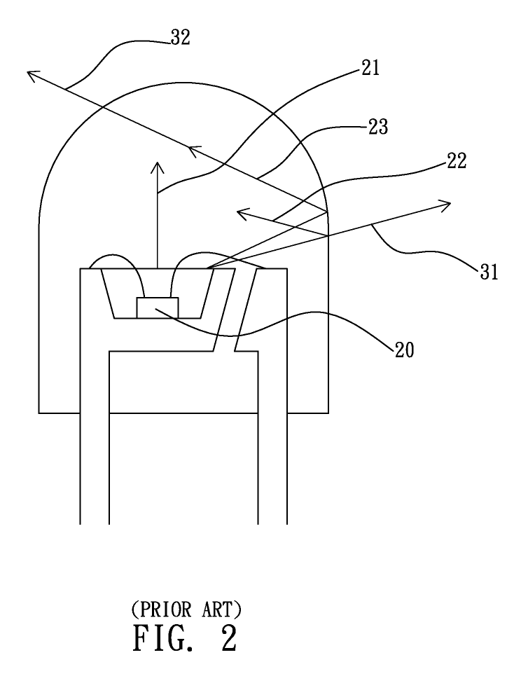

FIG. 3 illustrates the cross-sectional view of a LED packaging structure according to the present invention; and

FIG. 4 illustrates the cross-sectional view of another preferred embodiment of a LED packaging structure according to the present invention.

### DETAILED DESCRIPTION OF THE PREFERRED EMBODIMENT

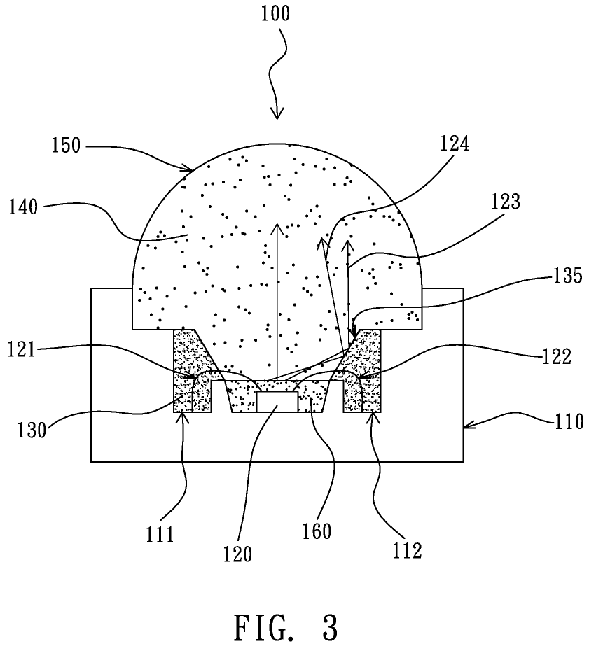

FIG. 3 illustrates the cross-sectional view of a light-emitted diode (LED) packaging structure according to the present invention.

With reference to FIG. 3, a LED packaging structure 100 according to the present invention is, for example but not limited to, a surface-mount LED, comprising a base 110, a chip 120, a first materials 130, a second material 140, and a ball lens 150.

The base 110 is disposed with a positive connection pad 111 and a negative connection pad 112 to be coupled with a printed circuit board (not shown). The base 110 is conventional art of a LED packaging structure. It is not the focus of the present invention and therefore will not be discussed hereafter.

The chip 120 is disposed upon the base 110 and coupled with the positive connection pad 111 and the negative connection pad 112 with two conducting wires 121 and 122, respectively, wherein the chip 120 may emit required electroluminescent light of different colors, which is a conventional are and will not be discussed hereafter.

The chip 120 is disposed with the first material 130 at least on its one side, for example but not limited to two sides, which has a first refraction index N₁₂ to refract or reflect the light 123 and 124 emitted from the chip 120, wherein the first material 130 is, for example but not limited to, air or an opaque material, which is, for example but not limited to, opaque epoxy resin, to refract the electroluminescent light emitted from the chip to the second material 140 in a proper angle.

The second material 140 is disposed upon the chip 120, has a second refraction index N₁₃. Furthermore, the second material 140 is separated with the first material 130 by an interface 135 to further refract the light 123 and 124 refracted from the first material 130 such that the light may emit nearly perpendicularly out from the ball lens 150 and in turn shorten the light path from the chip 120 as well as enhance the luminescent efficiency. The first refraction index N₁₂ of the first material 130 is lower than the second refraction index N₁₃ of the second material 140. Furthermore, the interface 135 is, for example but not limited to, an oblique surface, a curve, or a curved surface and the included angle θ between the interface 135 and the base 110 is, for example but not limited to, 10°˜90°, preferably 40°˜50°.

The ball lens 150 is disposed upon the second material 140 and forms a confined space with the base 110 to protect the base 110, the chip 120, the first material 130, and the second material 140. The arrangement is a conventional art and will not be discussed hereafter.

Also, the chip 120 according to the present invention is further disposed with phosphor 160 on its top, which may convert the light emitted from the chip 120 to a desired color. The phosphor 160 has the function of light conversion, which can convert the light 123 and 124 emitted from the chip 120 to a desired color, which is a conventional art and will not be discussed hereafter.

Consequently, with the LED packaging structure 100 according to the present invention, the light 123 and 124 emitted from the chip 120 refracts through the first material 130 and refracts again through the second material 140 such that the light may emit out nearly perpendicularly from the ball lens 150 and in turn shorten the light path of the light 123 and 124 from the chip 120 as well as enhance luminescent efficiency.

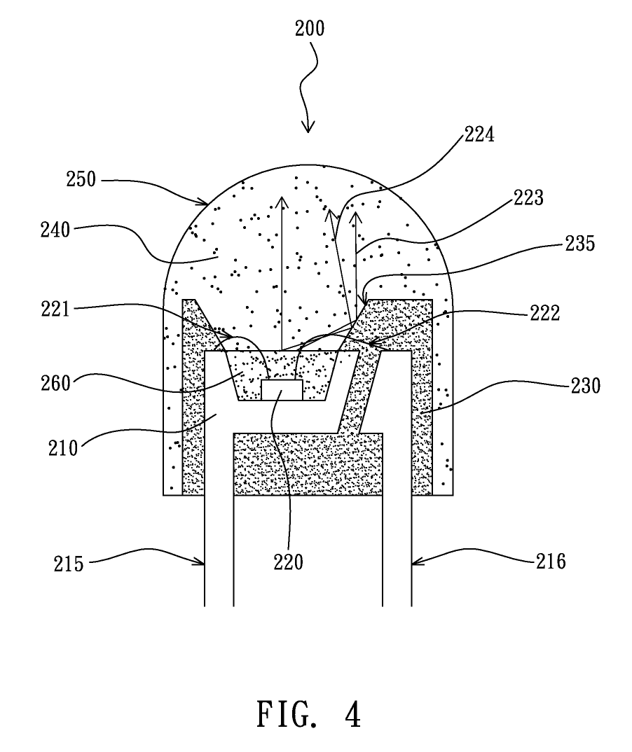

FIG. 4 illustrates the cross-sectional view of another preferred embodiment of a LED packaging structure according to the present invention.

With the reference to FIG. 4, a LED packaging structure 200 according to the present invention is, for example but not limited to, a direct in-line LED, comprising a base 210 disposed with a first leg 215, a second leg 216, a chip 220, a first materials 230, a second material 240, and a ball lens 150.

The base 210 is disposed with a first leg 215, which is, for example but not limited to, a positive leg, to be coupled with a printed circuit board (not shown). The base 210 is conventional art of a common LED packaging structure. It is not the focus of the present invention and therefore will not be discussed hereafter.

The second leg 216 is disposed on one side of the base 210 and is, for example but not limited to, a negative leg to be coupled with a printed circuit board (not shown). The first leg 215 and the second leg 216 are conventional art of a common LED packaging structure and therefore will not be discussed hereafter.

The chip 220 is disposed upon the base 210 and coupled with the first leg 215 and the second leg 216 by two conducting wires 221 and 222, respectively, wherein the chip 220 may emit required electroluminescent light of different colors, which is a conventional art and will not be discussed hereafter.

The chip 220 is disposed with the first material 230 at least on its one side, for example but not limited to two sides, which has a first refraction index N₂₂ to refract or reflect the light 223 and 224 emitted from the chip 220, wherein the first material 230 is, for example but not limited to, air or an opaque material, which is, for example but not limited to, opaque epoxy resin, capable of refracting the electroluminescent light 223 and 224 emitted out from the chip to the second material 240 in a proper angle.

The second material 240 is disposed upon the chip 220 and has a second refraction index N₂₃. The second material 240 is separated with the first material 230 by an interface 235 to further refract the light 223 and 224 refracted from the first material 230 such that the light may emit out nearly perpendicularly from the ball lens 250 and in turn shorten the light path from the chip 220 as well as enhance luminescent efficiency. The first refraction index N₂₂ of the first material 230 is lower than the second refraction index N₂₃ of the second material 240. Furthermore, the interface 235 is, for example but not limited to, an oblique surface, a curve, or a curved surface and the included angle θ between the interface 235 and the base 210 is, for example but not limited to, 10°˜90°, preferably 40°˜50°.

The ball lens 250 is disposed upon the second material 240 and forms a confined space with the base 210 to protect the base 210, the chip 220, the first material 230, and the second material 240. The arrangement is a conventional art and will not be discussed hereafter.

Also, the chip 220 according to the present invention is further disposed with phosphor 260 on its top, which may convert the light emitted from the chip 220 to a desired color. The phosphor 260 has the function of light conversion, which can convert the light emitted from the chip 220 to a desired color, which is a conventional art and will not be discussed hereafter.

Consequently, with the LED packaging structure 200 according to the present invention, the light 223 and 224 emitted from the chip 220 refracts through the first material 230 and refracts again through the second material 240 such that the light may emit out nearly perpendicularly from the ball lens 250 and in turn shorten the light path of the light 223 and 224 from the chip 220 as well as enhance the luminescent efficiency.

Consequently, with the implementation of a LED packaging structure according to the present invention, two materials with different refraction indexes to refract the light emitted from a chip and then emit out through a ball lens to enhance the luminescent efficiency of LEDs to overcome the drawbacks of conventional LED packaging structure.

It is appreciated that although the directional practice device of the present invention is used in a very limited space instead of practicing at the real playing field, effective and steady practice can be obtained as well. Further, it is very easy to set up and to operate the directional practice device of the present invention. These advantages are not possible to achieve with the prior art.

While the invention has been described with reference to the a preferred embodiment thereof, it is to be understood that modifications or variations may be easily made without departing from the spirit of this invention, which is defined by the appended claims.

What is claimed is:

1. A light-emitting diode packaging structure, comprising
a base disposed with a positive connection pad and a negative connection pad;
a chip disposed on the base and coupled with the positive and negative connection pads with two conducting wires, respectively;
a first material disposed on at least one side of the chip and having a first refraction index to refract the light emitted from the chip;
a second material disposed upon the chip, having a second refraction index, and separated with the first material with an interface therebetween to refract the light refracted from the first material; and
a ball lens disposed upon the second material and forming a confined space with the base;
whereby, the light emitted from the chip refracts through the first refraction material and the second refraction material and finally emits out from the ball lens.

2. The light-emitting diode packaging structure as defined in claim 1, wherein the first material is air.

3. The light-emitting diode packaging structure as defined in claim 1, wherein the first material is an opaque material.

4. The light-emitting diode packaging structure as defined in claim 3, wherein the first material is opaque epoxy resin.

5. The light-emitting diode packaging structure as defined in claim 1, wherein the first refraction index is lower than the second refraction index.

6. The light-emitting diode packaging structure as defined in claim 1, wherein the interface is an oblique surface, a curve, or a curved surface.

7. The light-emitting diode packaging structure as defined in claim 1, wherein the included angle θ is 10°˜90°.

8. The light-emitting diode packaging structure as defined in claim 1, wherein the chip is disposed with phosphor on its top, which may convert the light emitted from the chip to a desired color.

9. A light-emitting diode packaging structure, comprising
a base disposed with a first leg;
a second leg disposed on one side of the base;
a chip disposed on the base and coupled with the first leg and the second leg with two conducting wires, respectively;
a first material disposed on at least one side of the chip and having a first refraction index to refract the light emitted from the chip;
a second material disposed upon the chip, having a second refraction index, and separated with the first material with an interface therebetween to refract the light refracted from the first material; and
a ball lens disposed upon the second material and forming a confined space with the base, the first leg, and the second leg;
whereby, the light emitted from the chip refracts through the first refraction material and the second refraction material and finally emits out from the ball lens.

10. The light-emitting diode packaging structure as defined in claim 9, wherein the first material is air.

11. The light-emitting diode packaging structure as defined in claim 9, wherein the first material is an opaque material, which is epoxy resin.

12. The light-emitting diode packaging structure as defined in claim 11, wherein the first refraction index is lower than the second refraction index.

13. The light-emitting diode packaging structure as defined in claim 9, wherein the first leg is a positive leg and the second leg is the negative leg.

14. The light-emitting diode packaging structure as defined in claim 9, wherein the interface is an oblique surface, a curve, or a curved surface.

15. The light-emitting diode packaging structure as defined in claim 9, wherein the included angle θ is 10°˜90°.

16. The light-emitting diode packaging structure as defined in claim 9, wherein the chip is disposed with phosphor on its top, which may convert the light emitted from the chip to a desired color.
